(19) United States
(12) Patent Application Publication
(10) Pub. No.: US 2012/0043968 A1
(43) Pub. Date: Feb. 23, 2012

(54) VARIABLE EQUALIZER CIRCUIT

(75) Inventor: Shoji Kojima, Tokyo (JP)

(73) Assignee: ADVANTEST CORPORATION, Tokyo (JP)

(21) Appl. No.: 13/266,330

(22) PCT Filed: Mar. 31, 2010
(86) PCT No.: PCT/JP2010/002357

§ 371 Date: Oct. 26, 2011

(51) Int. Cl. G01R 31/02; H04B 3/14

(52) U.S. Cl. 324/537; 333/28 R

(57) ABSTRACT

A variable equalizer circuit equalizes a signal received via a transmission line from a device which is a communication partner device. A first resistor is arranged between an output terminal and a fixed voltage terminal, and is configured to have a variable resistance. A first capacitor is arranged between an output terminal and the fixed voltage terminal, and is arranged in parallel with the first resistor, and is configured to have a variable capacitance. A second resistor is arranged between an input terminal and the output terminal. A second capacitor is arranged in parallel with the second resistor between the input terminal and the output terminal. A shunt resistor is arranged on a path including the first capacitor and the second capacitor between the input terminal and the fixed voltage terminal.

### CROSS REFERENCE TO RELATED APPLICATIONS

This application is the U.S. National Stage of International Patent Application No. PCT/JP2010/002357 filed on Mar. 31, 2010, the disclosure of which is hereby incorporated by reference in its entirety.

### BACKGROUND OF THE INVENTION

1. Field of the Invention

The present invention relates to an equalizing circuit configured to equalize a signal.

2. Description of the Related Art

In order to test whether or not a semiconductor device operates normally after the semiconductor device is manufactured, a semiconductor test apparatus (which will also be referred to simply as the “test apparatus” hereafter) is employed. The test apparatus receives a signal (signal under test) output from a DUT (device under test), and compares the signal under test with an expected value, so as to judge the quality (Pass or Fail) of the DUT, or so as to measure the amplitude margin or the timing margin of the signal under test.

### RELATED ART DOCUMENTS

### Patent Documents

[patent document 1]

U.S. Pat. No. 6,937,054 B2 Specification
[patent document 2]

U.S. Pat. No. 7,394,331 B2 Specification

In general, a receiver circuit included in the test apparatus and the DUT are electrically connected to each other via a transmission line and a connector. The characteristic impedance Zo (e.g., 50Ω) of the transmission line or the connector is designed so as to provide impedance matching with a circuit block to be connected. Ideally, such an arrangement causes no waveform distortion due to signal transmission via the transmission line or the connector. However, in reality, it is impossible to provide such impedance matching over the entire pass band. Accordingly, such a transmission line or the like functions as an undesirable filter which causes waveform distortion. That is to say, the receiver circuit of the test apparatus receives a distorted waveform even if the waveform output from the DUT is satisfactory. This prevents the performance of the DUT itself from being measured.

By providing an equalizer circuit configured to compensate for the distortion of the signal under test as a component upstream of the receiver circuit (e.g., comparator) of the test apparatus, such an arrangement is capable of improving the waveform distortion of the signal under test due to the transmission line or the like. For example, Patent document 1 discloses an equalizer circuit monolithically integrated together with a differential amplifier. Also, Patent document 2 discloses a passive equalizer employing an LRC.

### SUMMARY OF THE INVENTION

The present invention has been made in view of such a situation. Accordingly, it is an exemplary purpose of an embodiment of the present invention to provide a variable equalizer circuit which is capable of adjusting the equalization level using a new approach that differs from conventional approaches.

An embodiment of the present invention relates to a variable equalizer circuit configured to equalize a signal received via a transmission line from a device which is a communication partner device. The variable equalizer circuit comprises: an input terminal connected to the transmission line; an output terminal; a first resistor arranged between the output terminal and a fixed voltage terminal, and configured to have a variable resistance; a first capacitor arranged between the output terminal and the fixed voltage terminal, arranged in parallel with the first resistor, and configured to have a variable capacitance; a second resistor arranged between the input terminal and the output terminal; a second capacitor arranged between the input terminal and the output terminal, and arranged in parallel with the second resistor; and a shunt resistor arranged on a path including the first capacitor and the second capacitor between the input terminal and the fixed voltage terminal.

Another embodiment of the present invention also relates to a variable equalizer circuit configured to equalize a signal received via a transmission line from a device which is a communication partner device. The variable equalizer circuit comprises: an input terminal connected to the transmission line; an output terminal; a first capacitor arranged between the output terminal and a fixed voltage terminal, and configured to have a variable capacitance; a second resistor arranged between the input terminal and the output terminal; a second capacitor arranged between the input terminal and the output terminal, and arranged in parallel with the second resistor; a shunt resistor arranged on a path comprising the first capacitor and the second capacitor between the input terminal and the fixed voltage terminal; and a level shifter configured to shift the voltage level of the output terminal, and to have a variable resistance between the output terminal and the fixed voltage terminal.

Such an equalizing circuit according to any one of the aforementioned embodiments functions as a high-frequency emphasis filter configured to emphasize the high-frequency component of the input signal, and has an advantage of being capable of adjusting the amount of boost and the time constant. Furthermore, such an equalizing circuit can be integrated on a semiconductor chip. Such an arrangement uses no inductor, thereby providing an advantage of a small circuit area, and an advantage of involving no unintended oscillation.

Yet another embodiment of the present invention relates to a test apparatus configured to receive a signal from a device under test via a transmission line, and to test the device under test. The test apparatus comprises: a variable equalizer circuit according to any one of the aforementioned embodiments, configured to equalize a signal received from the device under test; and a receiver circuit configured to receive an output signal from the variable equalizer circuit.

Such an embodiment is capable of testing a signal output from the device under test after it corrects signal distortion that occurs due to the transmission line or the like.

It should be noted that any combination of the aforementioned components may be made, and any component of the present invention or any manifestation thereof may be mutually substituted between a method, apparatus, and so forth, which are effective as an embodiment of the present invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram which shows a configuration of a test apparatus including a variable equalizer circuit according to an embodiment;

FIGS. 2A through 2C are circuit diagrams showing example configurations of a variable resistor and a variable capacitor;

FIGS. 3A through 3C are circuit diagrams each showing an example configuration of a level shifter;

FIG. 4 is a circuit diagram which shows a configuration of a variable equalizer circuit according to a comparison technique;

FIG. 5 is a circuit diagram which shows a simplified configuration of the variable equalizer circuit shown in FIG. 1;

FIG. 6 is an equivalent circuit diagram which shows a variable equalizer circuit in a static state;

FIGS. 7A and 7B are simulation waveform diagrams for the variable equalizer circuit shown in FIG. 1;

FIG. 8 is a circuit diagram which shows a configuration of a variable equalizer circuit according to a first modification;

FIG. 9 is a circuit diagram which shows a configuration of a variable equalizer circuit according to a second modification; and

FIG. 10 is a circuit diagram which shows a configuration of a variable equalizer circuit according to a fourth modification.

### DETAILED DESCRIPTION OF THE INVENTION

Description will be made below regarding preferred embodiments according to the present invention with reference to the drawings. The same or similar components, members, and processes are denoted by the same reference numerals, and redundant description thereof will be omitted as appropriate. The embodiments have been described for exemplary purposes only, and are by no means intended to restrict the present invention. Also, it is not necessarily essential for the present invention that all the features or a combination thereof be provided as described in the embodiments.

In the present specification, a state represented by the phrase “the member A is connected to the member B” includes a state in which the member A is indirectly connected to the member B via another member that does not affect the electric connection therebetween, in addition to a state in which the member A is physically and directly connected to the member B. Similarly, a state represented by the phrase “the member C is provided between the member A and the member B” includes a state in which the member A is indirectly connected to the member C, or the member B is indirectly connected to the member C via another member that does not affect the electric connection therebetween, in addition to a state in which the member A is directly connected to the member C, or the member B is directly connected to the member C.

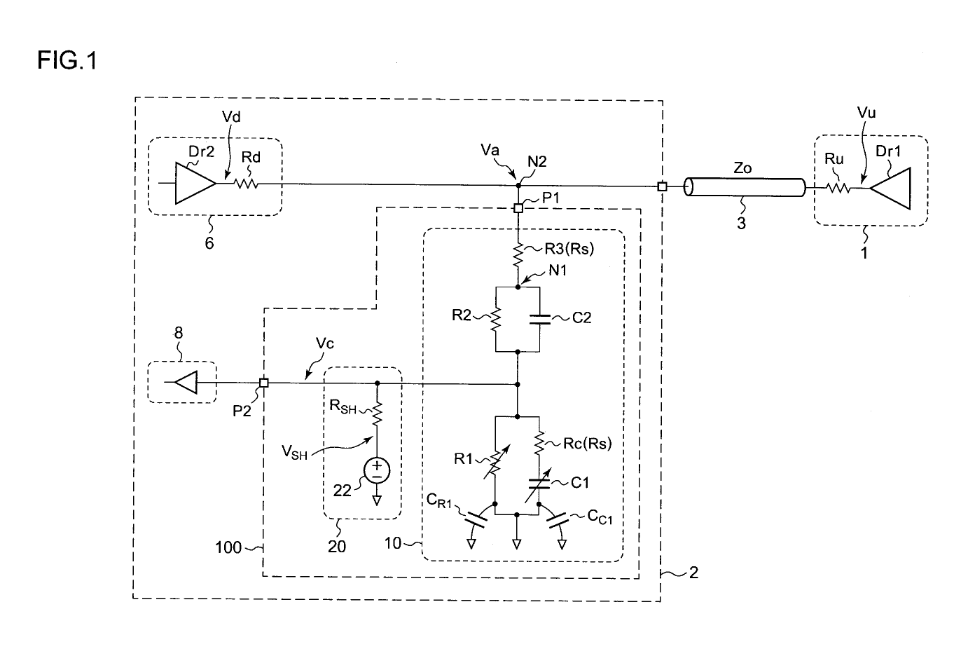

FIG. 1 is a circuit diagram which shows a test apparatus 2 including a variable equalizer circuit 100 according to an embodiment.

The test apparatus 2 is connected to a DUT 1 via a transmission line 3. The test apparatus 2 judges the quality of the DUT 1 or identifies the defective portions based upon a signal output from the DUT 1. The DUT 1 includes a driver Dr and an output resistor Ru. The driver Dr1 applies a signal under test Vu to one terminal of the transmission line 3.

A terminator 6 includes a terminal driver Dr2 and a terminal resistor Rd. The terminal driver Dr2 applies a terminal voltage Vd to the other terminal of the transmission line 3 via the terminal resistor Rd. The terminator 6 may function as a transmitter circuit (driver) configured to output a signal to the DUT 1.

A receiver circuit 8 receives a signal under test Vu output from the DUT 1. For example, the receiver circuit is configured as a comparator or a buffer. The test apparatus 2 compares the signal under test thus received by the receiver circuit 8 with an expected value so as to judge the quality of the DUT 1. Alternatively, the test apparatus 2 measures the amplitude margin or the timing margin of the signal under test.

With such a test system, waveform distortion occurs in the signal under test output from the DUT 1 when it passes through the transmission line 3, an unshown connector, or the like (which will be referred to as the “transmission line” or the like hereafter). In order to compensate for such waveform distortion, the test apparatus 2 includes a variable equalizer circuit 100 arranged as an upstream component of the receiver circuit 8.

Description will be made regarding a specific configuration of the variable equalizer circuit 100.

The variable equalizer circuit 100 equalizes a signal Va input via an input terminal P1 thereof from the DUT 1 which is a communication partner device, at the same time attenuates this signal, and outputs the signal thus processed to the receiver circuit 8 via an output terminal P2.

The variable equalizer circuit 100 includes an equalizing unit 10 and a level shifter 20.

The equalizing unit 10 includes a first resistor R1, a second resistor R2, a first capacitor C1, a second capacitor C2, and at least one shunt resistor Rs.

The first resistor R1 is configured as a variable resistor, the resistance value of which is changeable. The first resistor R1 is arranged between the output terminal P2 and a fixed voltage terminal (ground terminal). The first capacitor C1 is configured as a variable capacitor, the capacitance of which is changeable. The first capacitor C1 is arranged between the output terminal P2 and the ground terminal, in parallel with the first resistor R1. The second resistor R2 is arranged between the input terminal P1 and the output terminal P2. The second capacitor C2 is arranged between the input terminal P1 and the output terminal P2, in parallel with the second resistor R2.

At least one shunt resistor Rs is arranged on a path including the first capacitor C1 and the second capacitor C2 between the input terminal P1 and the ground terminal. FIG. 1 shows an arrangement in which the third resistor R3 and the fourth resistor Rc each function as a shunt resistor Rs.

The third resistor R3 is arranged between the input terminal P1 and a connection node (N1) that connects one terminal of the second resistor R2 and one terminal of the second capacitor C2. The third resistor R3 has resistance that is sufficiently greater than the characteristic impedance (50Ω) of the transmission line 3. For example, the third resistor R3 is preferably configured to have a resistance on the order of five to ten times the characteristic impedance of the transmission line 3. By setting the resistance of the third resistor R3 to be greater than the characteristic impedance of the transmission line 3, such an arrangement reduces the effects of the variable equalizer circuit 100 on the impedance matching between the terminator 6 and the DUT 1.

The fourth resistor Rc is arranged on a path in parallel with the first resistor R1, and in series with the first capacitor C1.

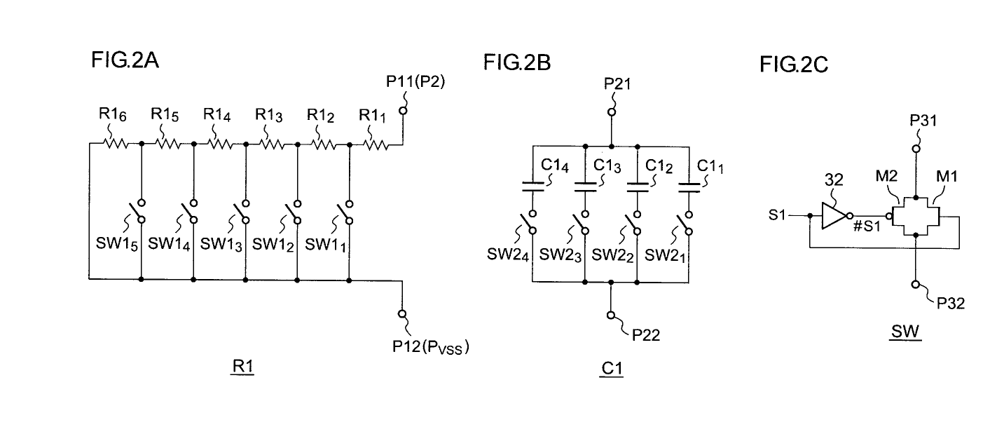

FIGS. 2A through 2C are circuit diagrams showing example configurations of the variable resistor and the variable capacitor. FIG. 2A shows an example configuration of the first resistor R1. The first resistor R1 includes a first terminal P11, a second terminal P12, multiple resistors R1₁ through R1₆ arranged in series between the first terminal P11 and the second terminal P12, and multiple switches SW1₁ through SW1₅ each arranged between a connection node (tap) of the adjacent resistor and the second terminal P12. By switching the states of the multiple switches SW1₁ through SW1₅ between the on state and the off state, such an arrangement is capable of switching the resistance of a path between the first terminal P11 and the second terminal P12. It should be noted that the switches SW1₁ through SW1₅ are arranged on the fixed voltage terminal (ground terminal) side. It should be noted that the number of resistors R1 can be determined as desired.

FIG. 2B shows an example configuration of a first capacitor C1. The first capacitor C1 includes multiple capacitors C1₁ through C1₄ arranged in parallel between a first terminal P21 and a second terminal P22. Multiple switches SW2₁ through SW2₄ are respectively arranged in series with the multiple capacitors C1₁ through C1₄. By switching the states of the multiple switches SW21 through SW24, such an arrangement is capable of switching the capacitance that develops between the first terminal P21 and the second terminal P22. The switches SW21 through SW24 are preferably arranged on the fixed voltage terminal (ground terminal) side. It should be noted that the number of multiple capacitors C1₁ through C1₄ can be determined as desired.

FIG. 2C is a circuit diagram which shows an example configuration of the switches SW1 and SW2 employed in FIGS. 2A and 2B. The switch SW is a so-called transfer gate, and includes a first transistor M1 configured as an N-channel MOSFET and a second transistor M2 configured as a P-channel MOSFET arranged in parallel between a first terminal P31 and a second terminal P32. A control signal S1 is input to the gate of the first transistor M1. A control signal #S1 obtained by inverting the control signal S1 by the inverter 32 is input to the gate of the second transistor M2. The state of a path between the first terminal P31 and the second terminal P32 is switched between the connection state and the disconnection state according to the control signal S1.

It should be noted that N-channel MOSFETs only or P-channel MOSFETs only may be employed, depending upon the relation between the electric potential at the first terminal P31 and the electric potential at the second terminal P32.

It should be noted that the configurations of the variable resistor and the variable capacitor are not restricted to such arrangements shown in FIGS. 2A through 2C. Rather, the topology thereof should be designed based upon the required resistance and capacitance.

Returning to FIG. 1, the level shifter 20 shifts the voltage level at the output terminal P2. In a case in which the receiver circuit 8 is configured as a comparator or a differential amplifier, such an arrangement has a limited input voltage range. Thus, by shifting the electric potential at the output terminal P2 by means of the level shifter 20 such that it matches the input voltage range of such a comparator or the like, such an arrangement can be expected to provide high-speed or high-precision operation.

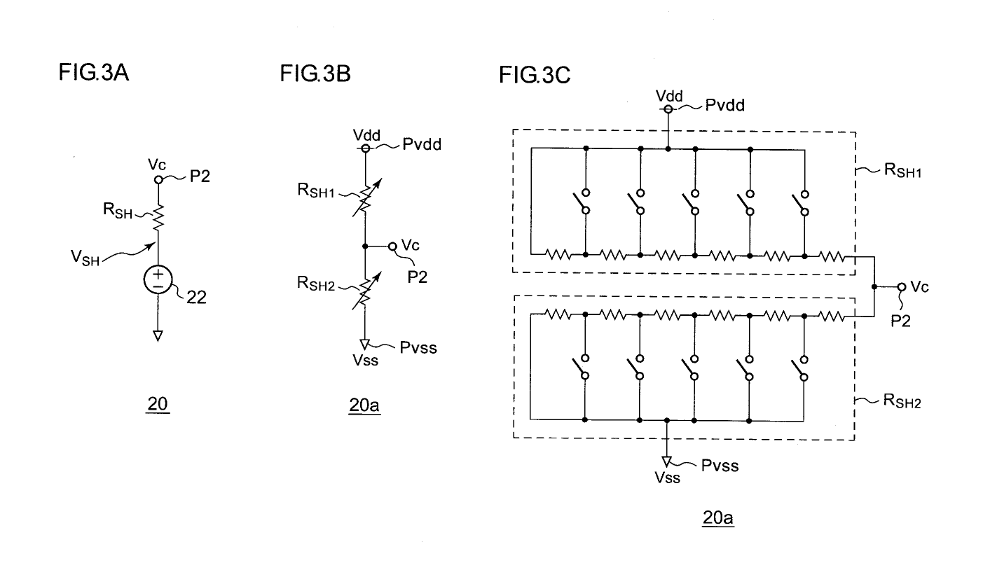

FIGS. 3A through 3C are circuit diagrams each showing an example configuration of the level shifter 20. The level shifter 20 shown in FIG. 3A includes a voltage source 22 configured to generate a first voltage V_{SH} and a fifth resistor R_{SH} arranged between the voltage source 22 and the output terminal P2. The level shifter 20 is capable of adjusting a level shifting amount by varying the first voltage V_{SH}.

FIG. 3B is a circuit diagram which shows another example configuration of the level shifter. A level shifter 20a includes a first fixed voltage terminal (power supply terminal) Pvdd to which a first fixed voltage (power supply voltage vdd) is to be applied, a second fixed voltage terminal (ground terminal) Pvss to which a second fixed voltage (ground voltage vss) that differs from the first fixed voltage (power supply voltage vdd) is to be applied, a first variable resistor R_{SH1} arranged between the first fixed voltage terminal Pvdd and the output terminal P2, and a second variable resistor R_{SH2} arranged between the second fixed voltage terminal Pvss and the output terminal P2.

Assuming that the level shifter shown in FIG. 3B is equivalent to the level shifter shown in FIG. 3A, the following Expression A1 holds true.

R_{SH}=R_{SH1}//R_{SH2}

V_{SH}=(vdd·R_{SH2}+vss·R_{SH1})/(R_{SH1}+R_{SH2}) (A1)

Here, “R1//R2” represents an operator that expresses the combined impedance of the resistors R1 and R2 arranged in parallel.

By solving Expression (A1) for R_{SH1} and R_{SH2}, the following Expression (A2) is obtained.

R_{SH1}=R_{SH}·(vdd−vss)/(V_{SH}−vss)

R_{SH2}=R_{SH}·(vdd−vss)/(Vdd−V_{SH})

FIG. 3C is a circuit diagram which shows a more specific configuration of the level shifter 20a shown in FIG. 3B. In the level shifter 20a shown in FIG. 3C, the variable resistor shown in FIG. 2A is employed for each of the first variable resistor R_{SH1 and} the second variable resistor R_{SH2}.

The first variable resistor R_{SH1} and the second variable resistor R_{SH2} preferably have a configuration in which the multiple switches SW are arranged on one fixed voltage terminal Pvdd side and a configuration in which the multiple switches SW are arranged on the other fixed voltage terminal Pvss side, respectively. Each switch SW has a parasitic capacitance (not shown). However, by arranging the switches SW on the fixed voltage terminal side, such an arrangement reduces the parasitic capacitance that occurs at the output terminal P2. As a result, such an arrangement reduces the effects of such parasitic capacitance on a signal transmitted via a node to which the output terminal P2 is connected.

The above is the configuration of the variable equalizer circuit 100. Next, returning to FIG. 1, description will be made regarding the operation thereof.

First, the DUT 1 outputs a signal under test to the test apparatus 2, and the signal under test thus output is input to the input terminal P1 of the variable equalizer circuit 100 shown in FIG. 1.

A combination of the second resistor R2 and the second capacitor C2 functions as a peaking filter for the signal Va input to the input terminal P1. The capacitance C₂ of the second capacitor C2 is determined so as to provide overcompensation.

Furthermore, the first resistor R1 is configured as a variable resistor and the first capacitor C1 is configured as a variable capacitor. By adjusting the first resistor R1 and the first capacitor C1, such an arrangement has a function of adjusting the overall characteristics of the variable equalizer circuit 100. Specifically, the first capacitor C1 having a capacitance C₁ suppresses overcompensation provided by the second capacitor C2. Here, the capacitances of the first capacitor C1 and the second capacitor C2 are set such that the relation C₂>C₁ holds true. Furthermore, the amount of boost by the equalizer can be controlled using the resistance of the first resistor R1.

With such a test system shown in FIG. 1, before the test operation, the user of the test apparatus can measure or calculate the amount of distortion or the frequency characteristics of such distortion that occurs in the signal output from the DUT 1 due to the effects of the transmission line 3 or the like. Accordingly, the user can determine the circuit constants of the first resistor R1 and the first capacitor C1 so as to cancel out distortion that occurs due to the transmission line 3 or the like.

The equalizing unit 10 equalizes the signal input to the input terminal P1, and at the same time attenuates this signal. The level shifter 20 shifts the level of the output signal of the equalizing unit 10, and outputs the resulting signal to the receiver circuit 8.

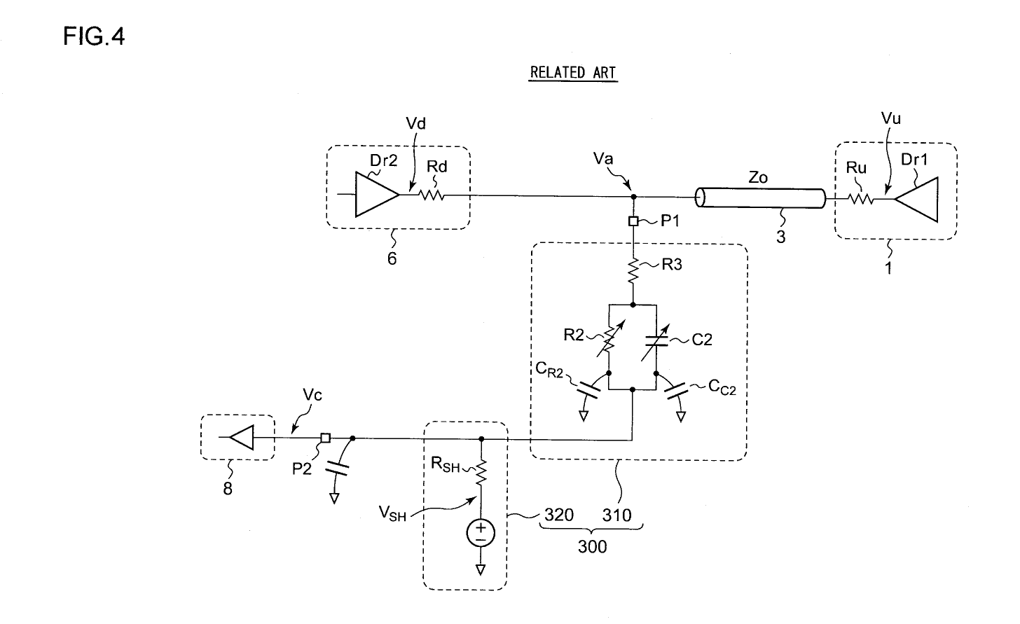

The above is the operation of the variable equalizer circuit 100. The advantage of the variable equalizer circuit 100 can be clearly understood in comparison with conventional techniques. FIG. 4 is a circuit diagram which shows a variable equalizer circuit 300 according to a conventional technique. The variable equalizer 300 includes an equalizing unit 310 and a level shifter 320. The equalizing unit 310 includes a third resistor R3, a second resistor R2 configured as a variable resistor, and a second capacitor C2 configured as a variable capacitor.

With such a variable equalizer circuit 300 shown in FIG. 4, if the second resistor R2 is configured as a variable resistor having a configuration as shown in FIG. 2A, the parasitic capacitance C_{R2} of each switch is connected between the signal line and the ground terminal. Similarly, if the second capacitor C2 is configured as a variable capacitor as shown in FIG. 2B, the parasitic capacitance C_{C2} of the switch is connected between the signal line and the ground terminal. Such parasitic capacitances C_{R2} and C_{C2} lead to a dulled signal being input to the receiver circuit 8.

That is to say, such parasitic capacitances counteract the desired functions of the equalizer circuit. This means that there is a reduction in the response speed of the circuit.

In contrast, with the variable equalizer circuit 100 shown in FIG. 1, the second resistor R2 and the second capacitor C2 are respectively configured as a fixed resistor and a fixed capacitor, and the first resistor R1 and the first capacitor C1 are respectively configured as a variable resistor and a variable capacitor. With such an arrangement, the parasitic capacitance C_{R1} of the first resistor R1 and the parasitic capacitance C_{C1} of the first capacitor are not directly connected to a signal line via which a signal is transmitted from the input terminal P1 to the output terminal P2. Thus, such an arrangement provides a circuit with an improved response speed.

In addition to such an advantage, the variable equalizer circuit 100 has the following advantages.

The variable equalizer circuit 100 is capable of changing the amount of boost and the time constant by adjusting the first capacitor C1 and the first resistor R1.

Furthermore, the variable equalizer circuit 100 includes resistors, capacitors, and transistors. This means that the variable equalizer circuit 100 has a configuration suitable for integration on a semiconductor chip. Furthermore, the variable equalizer circuit 100 includes no inductor. Thus, such an arrangement provides an advantage of a reduced circuit area and an advantage that unintended oscillation does not occur.

Furthermore, the variable equalizer circuit 100 attenuates the signal at the same time as the equalizing operation. Accordingly, such an arrangement reduces the voltage level to be input to the receiver circuit 8. Thus, such an arrangement allows the receiver circuit 8 to be configured using high-speed and low-voltage transistors. Thus, such an arrangement is capable of receiving a high-speed signal.

Furthermore, by providing the third resistor R3, such an arrangement reduces the effects of the variable equalizer circuit 100 on the impedance matching between the terminator 6 and the DUT 1. Furthermore, by providing the fourth resistor Rc, such an arrangement provides improved bandwidth characteristics.

Next, description will be made regarding a qualitative analysis of the variable equalizer circuit 100.

Here it is supposed that impedance matching is provided between the output resistor Ru of the DUT 1, the terminal resistor Rd of the terminator 6, and the characteristic impedance Zo of the transmission line 3. In this case, the impedance at the node N2 is represented by Zo/2.

Furthermore, the resistance of the third resistor R3 is sufficiently higher than the characteristic impedance Zo as described above. Accordingly, it can be assumed that the effects of the variable equalizer circuit 100 on the impedance matching between the terminator 6 and the DUT 1 are negligible.

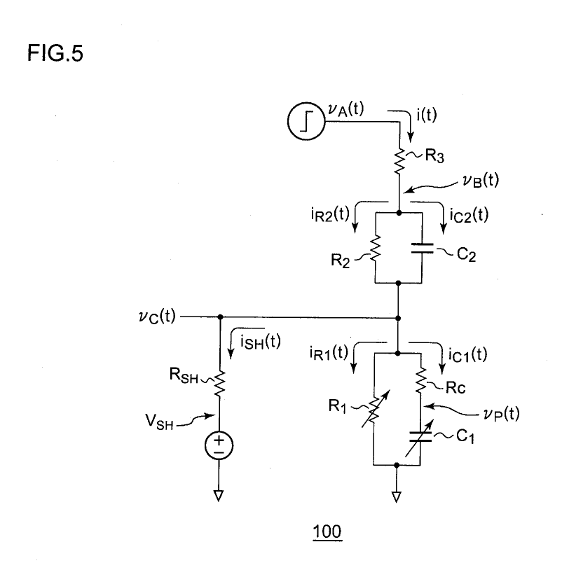

FIG. 5 is a circuit diagram obtained by simplifying the configuration of the variable equalizer circuit 100 shown in FIG. 1.

R₁ represents the resistance of the first resistor R1, R₂ represents the resistance of the second resistor R2, R₃ represents the resistance of the third resistor R3, R_{c} represents the resistance of the fourth resistor Rc, C₁ represents the capacitance of the first capacitor C1, and C₂ represents the capacitance of the second capacitor C2.

First, the following Expression (1) is obtained using Kirchhoff's current law.

i(t)=i_{R2}(t)+i_{C2}(t)=i_{SH}(t)+i_{R1}(t)+i_{C1}(t) (1)

Each current is obtained as represented by Expressions (2) through (6). Here, G₁=1/R₁, G₂=1/R₂, G₃=1/R₃, and G_{SH}=1/R_{SH}. It should be noted that i_{ci} is separately calculated.

$$\begin{matrix}i ( t ) = {G}_{3} \cdot ( {v}_{A} ( t ) - {v}_{B} ( t ) ) & ( 2 ) \\ {i}_{R 2} ( t ) = {G}_{2} \cdot ( {v}_{B} ( t ) - {v}_{C} ( t ) ) & ( 3 ) \\ {i}_{C 2} ( t ) = {C}_{2} \cdot \frac{d}{d t} ( {v}_{B} ( t ) - {v}_{C} ( t ) ) & ( 4 ) \\ {i}_{SH} ( t ) = {G}_{SH} \cdot ( {v}_{C} ( t ) - {V}_{SH} ) & ( 5 ) \\ {i}_{R 1} ( t ) = {G}_{1} \cdot {v}_{C} ( t ) & ( 6 )\end{matrix}$$

By generating the Laplace transform of the Expressions (1) through (6), the following Expressions (1)′ through (6)′ are obtained.

$$\begin{matrix}I ( s ) = {I}_{R 2} ( s ) + {I}_{C 2} ( s ) = {I}_{SH} ( s ) + {I}_{R 1} ( s ) + {I}_{C 1} ( s ) & {( 1 )}^{′} \\ I ( s ) = {G}_{3} \cdot ( {V}_{A} ( s ) - {V}_{B} ( s ) ) & {( 2 )}^{′} \\ {I}_{R 2} ( s ) = {G}_{2} \cdot ( {V}_{B} ( s ) - {V}_{C} ( s ) ) & {( 3 )}^{′} \\ {I}_{C 2} ( s ) = {C}_{2} \cdot \{ s \cdot ( {V}_{B} ( s ) - {V}_{C} ( s ) ) - ( {v}_{B} ( 0 - ) - {v}_{C} ( 0 - ) ) \} & ( {4}^{′} ) \\ {I}_{SH} ( s ) = {G}_{SH} \cdot ( {V}_{C} ( s ) - \frac{1}{s} {V}_{SH} ) & {( 5 )}^{′} \\ {I}_{R 1} ( s ) = {G}_{1} \cdot {V}_{C} ( s ) & {( 6 )}^{′}\end{matrix}$$

Next, directing attention to the relation between the i_{C1}(t) and v_{c}(t), the following Expression (7) is obtained. By generating the Laplace transform of Expression (7), Expression (7)′ is obtained. Furthermore, Expression (7)′ is solved with respect to I_{C1}(s) by removing V_{P}(s), thereby obtaining the following Expression (8).

$$\begin{matrix}{i}_{C 1} ( t ) = \frac{1}{{R}_{C}} ( {v}_{C} ( t ) - {v}_{P} ( t ) ) = {C}_{1} \cdot \frac{{v}_{P} ( t )}{d t} & ( 7 ) \\ {I}_{C 1} ( s ) = \frac{1}{{R}_{C}} ( {V}_{C} ( s ) - {V}_{P} ( s ) ) = {C}_{1} \cdot ( s \cdot {V}_{P} ( s ) - {v}_{P} ( 0 - ) ) & {( 7 )}^{′} \\ {I}_{C 1} ( s ) = {C}_{1} \cdot \frac{s \cdot {V}_{C} ( s ) - {v}_{P} ( 0 - )}{s \cdot {C}_{1} \cdot {R}_{C} + 1} & ( 8 )\end{matrix}$$

By substituting Expressions (2)′ through (6)′ and (8) into Expression (1)′, Expression (9) is obtained.

$$\begin{matrix} {G}_{3} \cdot ( {V}_{A} ( s ) - {V}_{B} ( s ) ) & ( 9 ) Left \\ = ( {G}_{2} + s \cdot {C}_{2} ) \cdot ( {V}_{B} ( s ) - {V}_{C} ( s ) ) - {C}_{2} \cdot ( {v}_{B} ( 0 - ) - {v}_{C} ( 0 - ) ) & ( 9 ) Middle \\ = {G}_{DH} \cdot ( {V}_{C} ( s ) - \frac{1}{s} {V}_{SH} ) + {G}_{1} \cdot {V}_{C} ( s ) + {C}_{1} \cdot s \cdot \frac{{V}_{C} ( s ) - {v}_{P} ( 0 - )}{s \cdot {C}_{1} \cdot {R}_{C} + 1} & ( 9 ) Right\end{matrix}$$

The following Expression (10) is obtained from the left side and the middle of Expression (9).

$${V}_{B} ( s ) = \frac{{V}_{C} ( s ) \cdot ( s \cdot {C}_{2} + {G}_{2} ) + {C}_{2} \cdot ( {v}_{B} ( 0 - ) - {v}_{C} ( 0 - ) ) + {V}_{A} ( s ) \cdot {G}_{3}}{s \cdot {C}_{2} + {G}_{2} + {G}_{3}} \qquad ( 10 )$$

Here, defining v_{A}(t) to be a step function represented by Expression (11), the Laplace transform of v_{A}(t) is represented by Expression (12). It should be noted that the value of V_{A1} does not appear in Expression (12). However, the information with respect to the initial state is included in Vc(0−) in expression (10), and accordingly, this poses no difficulty in the downstream calculation step. Furthermore, assuming that the circuit is static at the time point t<0, the following Expression (13) holds true.

$$\begin{matrix}{v}_{A} ( t ) = \{ \begin{matrix}{v}_{A 1} & … & ( t < 0 ) \\ {v}_{A 2} & … & ( 0 \leq t )\end{matrix} \\ ↓ & ( 11 ) \\ {V}_{a} ( s ) = \frac{{V}_{A 2}}{s} & ( 12 ) \\ {v}_{P} ( 0 - ) = {v}_{C} ( 0 - ) & ( 13 )\end{matrix}$$

Expression (10) and Expression (12) are substituted into the left side of Expression (9), and Expression (13) is substituted into the right side of Expression (9), thereby obtaining Expression (14). Furthermore, Expression (14) is transformed so as to provide the following Expression (15).

$$\begin{matrix}{G}_{3} \cdot ( \frac{{V}_{A 2}}{s} - \frac{\begin{matrix}{V}_{C} ( s ) \cdot ( s \cdot {C}_{2} + {G}_{2} ) + {C}_{2} \cdot \\ ( {v}_{B} ( 0 - ) - {v}_{C} ( 0 - ) ) + {V}_{A} ( s ) \cdot {G}_{3}\end{matrix}}{s \cdot {C}_{2} + {G}_{2} + {G}_{3}} ) = {G}_{SH} \cdot ( {V}_{C} ( s ) - \frac{1}{s} {V}_{SH} ) + {G}_{1} \cdot {V}_{C} ( s ) + {C}_{1} \cdot \frac{s \cdot {V}_{C} ( s ) - {v}_{C} ( 0 - )}{s \cdot {C}_{1} \cdot {R}_{C} + 1} & ( 14 ) \\ {V}_{C} ( s ) = \frac{1}{s} \cdot \frac{A \cdot {s}^{2} + T \cdot s + U}{{s}^{2} + P \cdot s + Q} & ( 15 )\end{matrix}$$

The coefficients A, T, U, P, and Q in Expression (15) are represented by the following Expressions (15-1) through (15-5).

$$\begin{matrix}A = \cdot \frac{\begin{matrix}{R}_{C} \cdot \{ {V}_{A 2} \cdot {G}_{3} - ( {v}_{B} ( 0 - ) - {v}_{C} ( 0 - ) ) \cdot {G}_{3} + {V}_{SH} \cdot {G}_{SH} \} + \\ {v}_{C} ( 0 - )\end{matrix}}{{R}_{C} \cdot ( {G}_{3} + {G}_{SH} + {G}_{1} ) + 1} & ( 15 \text{-} 1 ) \\ T = \frac{\begin{matrix}\begin{matrix}{V}_{A 2} \cdot {G}_{3} \cdot \{ {C}_{2} + {C}_{1} \cdot {R}_{C} \cdot {G}_{2} \} - \\ {G}_{3} \cdot {C}_{2} \cdot ( {v}_{B} ( 0 - ) - {v}_{C} ( 0 - ) ) +\end{matrix} \\ {V}_{SH} \cdot {G}_{SH} \cdot \{ {C}_{2} + {C}_{1} \cdot {R}_{C} \cdot ( {G}_{2} + {G}_{3} ) \} + \\ {v}_{C} ( 0 - ) \cdot {C}_{1} \cdot ( {G}_{2} + {G}_{3} )\end{matrix}}{{C}_{1} \cdot {C}_{2} \cdot \{ {R}_{C} \cdot ( {G}_{3} + {G}_{SH} + {G}_{1} ) + 1 \}} & ( 15 \text{-} 2 ) \\ U = \frac{{V}_{A 2} \cdot {G}_{3} \cdot {G}_{2} + {V}_{SH} \cdot {G}_{SH} \cdot ( {G}_{2} + {G}_{3} )}{{C}_{1} \cdot {C}_{2} \cdot \{ {R}_{C} \cdot ( {G}_{3} + {G}_{SH} + {G}_{1} ) + 1 \}} & ( 15 \text{-} 3 ) \\ P = \frac{\begin{matrix}{G}_{3} \cdot ( {C}_{1} \cdot {R}_{C} \cdot {G}_{2} + {C}_{2} ) + ( {G}_{SH} + {G}_{1} ) \cdot \\ \{ {C}_{2} + {C}_{1} \cdot {R}_{C} \cdot ( {G}_{2} + {G}_{3} ) \} + {C}_{1} \cdot ( {G}_{2} + {G}_{3} )\end{matrix}}{{C}_{1} \cdot {C}_{2} \cdot \{ {R}_{C} \cdot ( {C}_{3} + {G}_{SH} + {G}_{1} ) + 1 \}} & ( 15 \text{-} 4 ) \\ Q = \frac{{G}_{2} \cdot {G}_{3} + ( {G}_{SH} + {G}_{1} ) \cdot ( {G}_{2} + {G}_{3} )}{{C}_{1} \cdot {C}_{2} \cdot \{ {R}_{C} \cdot ( {G}_{3} + {G}_{SH} + {G}_{1} ) + 1 \}} & ( 15 \text{-} 5 )\end{matrix}$$

Assuming that partial fraction decomposition of Expression (15) can be done as represented by Expression (16), α, β, γ, ω₁, and ω₂ are calculated. If α, β, γ, ω₁, and ω₂ are all real numbers, the inverse Laplace transform of Expression (16) can be calculated, thereby obtaining the response V_{c}(t) on the time domain. The reason why such a partial fraction decomposition can be done as represented by Expression (16) is that the variable equalizer circuit 100 shown in FIG. 1 is configured using resistors and capacitors, and accordingly, the response of the circuit does not involve oscillation. Expression (16) is reduced, thereby obtaining the following Expression (17).

$$\begin{matrix}{V}_{C} ( s ) = \frac{γ}{s} + \frac{α}{s + {ω}_{1}} + \frac{β}{s + {ω}_{2}} & ( 16 ) \\ {V}_{C} ( s ) = \frac{1}{s} \cdot \frac{\begin{matrix}( γ + α + β ) \cdot {s}^{2} + ( γ \cdot ( {ω}_{1} + {ω}_{2} ) + α \cdot {ω}_{2} + β \cdot {ω}_{1} ) \cdot \\ s + γ \cdot {ω}_{1} \cdot {ω}_{2}\end{matrix}}{{s}^{2} + ( {ω}_{1} + {ω}_{2} ) \cdot s + {ω}_{1} \cdot {ω}_{2}} & ( 17 )\end{matrix}$$

Expression (15) must be identically equivalent to Expression (17). Thus, by making a comparison of each term between these Expressions, the following Expressions (18-1) through (18-5) are obtained.

A=γ+α+β (18-1)

T=γ·(ω₁+ω₂)+α·ω₂+β ω₁ (18-2)

U=γ·ω₁·ω₂ (18-3)

P=ω₁+ω_{2 (}18-4)

Q=ω₁ω₂ (18-5)

By solving the Expressions (18-1) through (18-5), the following Expressions (19-1) through (19-5) are obtained.

$$\begin{matrix} γ = \frac{U}{Q} & ( 19 \text{-} 1 ) \\ {ω}_{1} = \frac{1}{2} ( P + \sqrt{{P}^{2} - 4 \cdot Q} ) & ( 19 \text{-} 2 ) \\ {ω}_{2} = \frac{1}{2} ( P - \sqrt{{P}^{2} - 4 \cdot Q} ) & ( 19 \text{-} 3 ) \\ α = \frac{- 1}{2 \cdot \sqrt{{P}^{2} - 4 \cdot Q}} \cdot \{ 2 \cdot T - \frac{U}{Q} \cdot ( P - \sqrt{{P}^{2} - 4 \cdot Q} ) - A \cdot ( P + \sqrt{{P}^{2} - 4 \cdot Q} ) \} & ( 19 \text{-} 4 ) \\ β = \frac{1}{2 \cdot \sqrt{{P}^{2} - 4 \cdot Q}} \cdot \{ 2 \cdot T - \frac{U}{Q} \cdot ( P + \sqrt{{P}^{2} - 4 \cdot Q} ) - A \cdot ( P - \sqrt{{P}^{2} - 4 \cdot Q} ) \} & ( 19 \text{-} 5 )\end{matrix}$$

The inverse Laplace transform of Expression (16) is calculated, thereby obtaining the following Expression (20).

$$\begin{matrix}{V}_{C} ( s ) = \frac{γ}{s} + \frac{α}{s + {ω}_{1}} + \frac{β}{s + {ω}_{2}} \\ ↓ {- 1}^{} & ( 16 ) \\ {v}_{C} ( t ) = γ + α \cdot exp ( - {ω}_{1} \cdot t ) + β \cdot exp ( - {ω}_{2} \cdot t ) & ( 20 )\end{matrix}$$

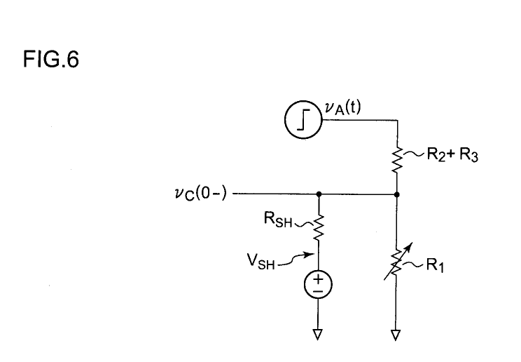

Expression (20) is defined only in the range 0<t. In the range t<0, assuming that the circuit is in the static state, v_{c}(0−) is calculated. FIG. 6 is an equivalent circuit diagram of a variable equalizer circuit in the static state. In the static state, each capacitor is regarded as being in an open state. In the range t<0, the circuit shown in FIG. 5 provides the same voltage state and the same current state as those of the circuit shown in FIG. 6. Thus, v_{c}(0−) is calculated based upon the circuit model shown in FIG. 6, thereby obtaining the following Expression (21).

$${v}_{c} ( 0 - ) = \frac{{V}_{A 1} \cdot {R}_{SH} \cdot {R}_{1} + {V}_{SH} \cdot {R}_{1} \cdot ( {R}_{2} + {R}_{3} )}{{R}_{SH} \cdot {R}_{1} + ( {R}_{SH} + {R}_{1} ) \cdot ( {R}_{2} + {R}_{3} )} \qquad ( 21 )$$

The response waveform represented by Expression (20) is attached to the response waveform represented by Expression (21) at the time point t=0, thereby obtaining the response waveform v_{c}(t) which represents the response that occurs when a step input represented by Expression (11) is applied.

Next, the attenuation rate is calculated.

Assuming that v_{A}(t) is represented by a step function as represented by Expression (11), the circuit is in the static state at the time point t=∞. Thus, v_{c}(∞) can be calculated as represented by the following Expression (22) based upon the equivalent circuit shown in FIG. 6. Furthermore, the attenuation rate ATT is represented by the following Expression (23).

$$\begin{matrix}{v}_{c} ( ∞ ) = \frac{{V}_{A 2} \cdot {R}_{SH} \cdot {R}_{1} + {V}_{SH} \cdot {R}_{1} \cdot ( {R}_{2} + {R}_{3} )}{{R}_{SH} \cdot {R}_{1} + ( {R}_{SH} + {R}_{1} ) \cdot ( {R}_{2} + {R}_{3} )} & ( 22 ) \\ A T T = \frac{{v}_{c} ( ∞ ) - {v}_{c} ( 0 - )}{{V}_{A 2} - {V}_{A 1}} = \frac{1}{1 + ( \frac{1}{{R}_{SH}} + \frac{1}{{R}_{1}} ) \cdot ( {R}_{2} + {R}_{3} )} & ( 23 )\end{matrix}$$

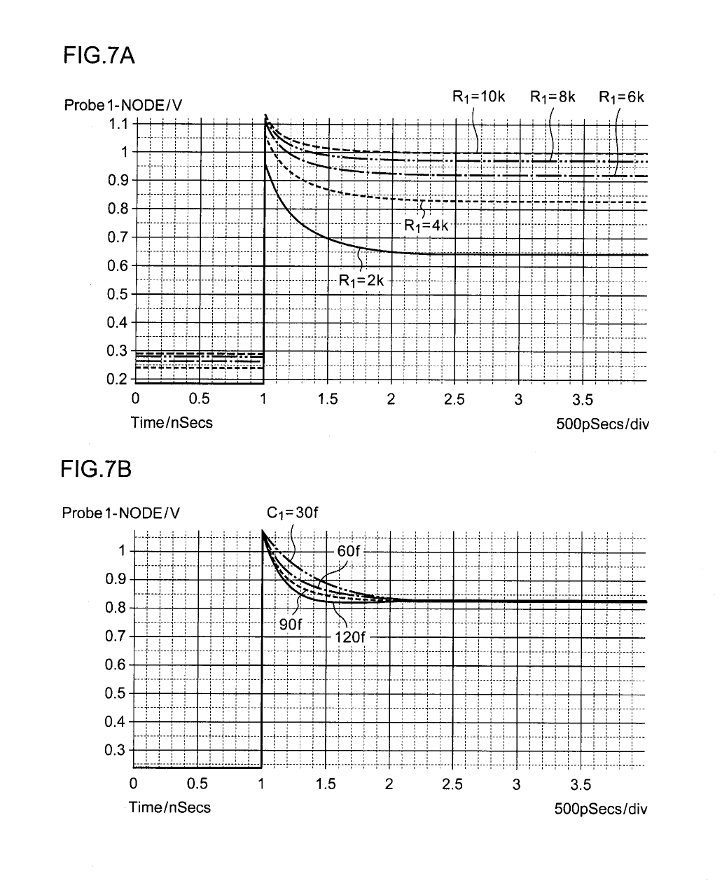

FIGS. 7A and 7B are simulation waveform diagrams for the variable equalizer circuit 100 shown in FIG. 1.

FIG. 7A shows waveforms for when the parameter of the resistance value R₁ of the first resistor R1 is set to 2 kΩ, 4 kΩ, 6 kΩ, 8 kΩ, and 10 kΩ. The other circuit constants are as follows.

R₂=1.75 kΩ

R₃=250 Ω

R_{c}=2 kΩ

C₁=60 fF

C₂=300 fF

It can be understood that the amount of boost can be controlled mainly by changing the resistance value R1 of the first resistor R1.

FIG. 7B shows waveforms when the parameters of the capacitance value C₁ of the first capacitor C1 is set to 30 fF, 60 fF, 90 fF, and 120 fF. The resistance value R₁ is 4 kΩ, and the other circuit constants are the same as those in the above description. It can be understood that the time constant can be controlled by changing the capacitance value C₁ of the first capacitor C1.

The above-described embodiment has been described for exemplary purposes only, and is by no means intended to be interpreted restrictively. Rather, it can be readily conceived by those skilled in this art that various modifications may be made by making various combinations of the aforementioned components or processes, which are also encompassed in the technical scope of the present invention. Description will be made below regarding such modifications.

### [First Modification]

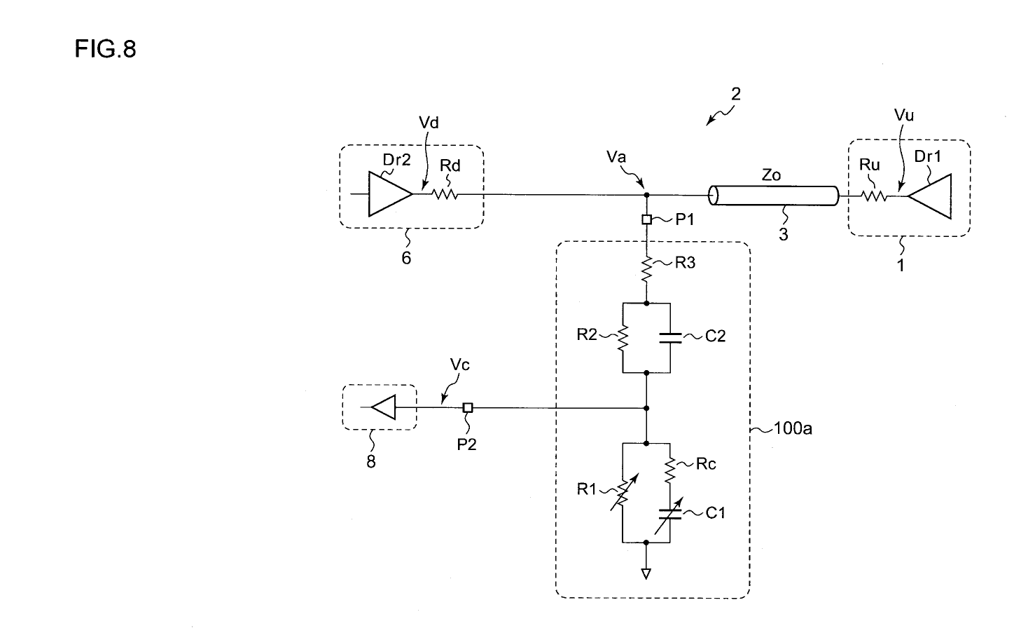

FIG. 8 is a circuit diagram which shows a configuration of a variable equalizer circuit 100a according to a first modification. The variable equalizer circuit 100a shown in FIG. 8 has a configuration obtained by eliminating the level shifter 20 from the configuration of the variable equalizer circuit 100 shown in FIG. 1. With such an arrangement, with R_{SH} set to ∞, Expressions (2) through (23) hold true without change. In a case in which the output signal of the variable equalizer circuit 100a is within the input voltage range of the receiver circuit 8 without the need to level-shift the output signal of the variable equalizer circuit 100a, the level shifter 20 can be eliminated.

### [Second Modification]

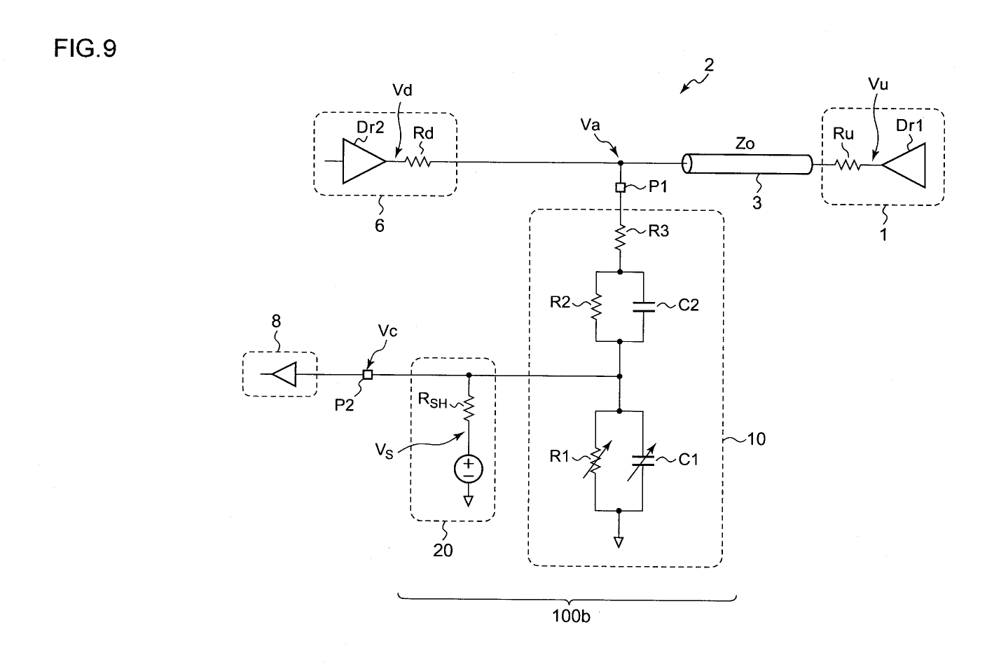

FIG. 9 is a circuit diagram which shows a variable equalizer circuit 100b according to a second modification. The variable equalizer circuit 100b shown in FIG. 9 has a configuration obtained by eliminating the fourth resistor Rc from the configuration of the variable equalizer circuit 100 shown in FIG. 1. With such an arrangement, with Rc as 0, Expressions (2) through (23) holds true without change.

### [Third Modification]

A third modification has a configuration obtained by eliminating the third resistor R3 from the configuration of the variable equalizer circuit 100 shown in FIG. 1. In a case in which the second resistor R2, the first resistor R1, and the fourth resistor Rc each have a large resistance as compared with the characteristic impedance Zo of the transmission line 3, the variable equalizer circuit 100 does not affect the impedance matching. Thus, in this case, the third resistor R3 can be eliminated.

### [Fourth Modification]

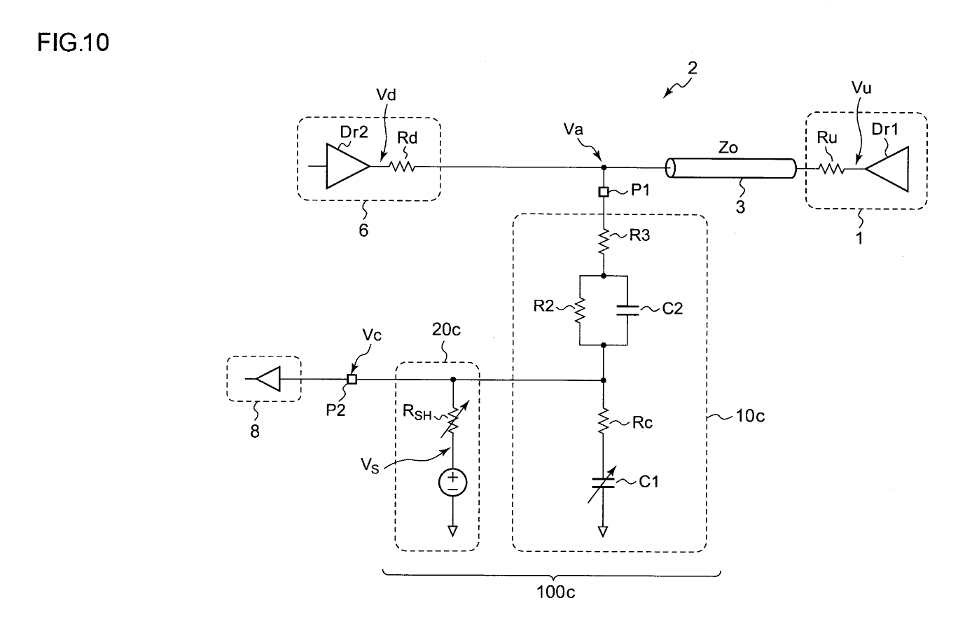

FIG. 10 is a circuit diagram which shows a configuration of a variable equalizer circuit 100c according to a fourth modification. The variable equalizer circuit 100c shown in FIG. 10 has a configuration obtained by eliminating the first resistor R1 from the configuration of the variable equalizer circuit 100 shown in FIG. 1. Furthermore, with such a configuration, the resistor R_{SH} of the level shifter 20c is configured as a variable resistor instead of including the first resistor R1. The level shifter 20c is configured to be capable of changing the resistance component R_{SH} between the output terminal P2 and the fixed voltage terminal (ground terminal or power supply terminal). With such an arrangement, with R1 as ∞, Expressions (2) through (23) hold true without change.

Some modifications described above may be combined with each other.

For example, the first modification may be combined with at least one from the second and third modifications.

For example, the second modification may be combined with at least one from the first, third, and fourth modifications.

For example, the third modification may be combined with at least one from the first, second, and fourth modifications.

For example, the fourth modification may be combined with at least one from the second and third modifications.

Various combinations and various modifications may be made without harming the advantages of the present invention, which are readily conceived by those skilled in this art.

Description has been made in the aforementioned embodiments regarding an arrangement in which the variable equalizer circuit 100 is employed in the test apparatus 2. However, an application of the variable equalizer circuit 100 is not restricted to such an arrangement. Rather, such a variable equalizer circuit can be applied to various kinds of devices configured to receive a signal from an external circuit.

Description has been made regarding the present invention with reference to the embodiments. However, the above-described embodiments show only the mechanisms and applications of the present invention for exemplary purposes only, and are by no means intended to be interpreted restrictively. Rather, various modifications and various changes in the layout can be made without departing from the spirit and scope of the present invention defined in appended claims.

What is claimed is:

1. A variable equalizer circuit configured to equalize a signal received via a transmission line from a device which is a communication partner device, the variable equalizer circuit comprising:
an input terminal connected to the transmission line;
an output terminal;
a first resistor arranged between the output terminal and a fixed voltage terminal, and configured to have a variable resistance;
a first capacitor arranged between the output terminal and the fixed voltage terminal, arranged in parallel with the first resistor, and configured to have a variable capacitance;
a second resistor arranged between the input terminal and the output terminal;
a second capacitor arranged between the input terminal and the output terminal, and arranged in parallel with the second resistor; and
a shunt resistor arranged on a path including the first capacitor and the second capacitor between the input terminal and the fixed voltage terminal.

2. A variable equalizer circuit according to claim 1, wherein the shunt resistor comprises a third resistor arranged between the input terminal and a connection node that connects the second resistor and the second capacitor.

3. A variable equalizer circuit according to claim 1, wherein the shunt resistor comprises a fourth resistor arranged in series with the first capacitor so as to form a path that is in parallel with the first resistor.

4. A variable equalizer circuit according to claim 1, further comprising a level shifter configured to shift the voltage level of the output terminal.

5. A variable equalizer circuit according to claim 4, wherein the level shifter comprises:
a voltage source configured to generate a first voltage; and
a fifth resistor arranged between the voltage source and the output terminal.

6. A variable equalizer circuit according to claim 4, wherein the level shifter comprises:
a first fixed voltage terminal to which a first fixed voltage is to be applied;
a second fixed voltage terminal to which a second fixed voltage that differs from the first fixed voltage is to be applied;
a first variable resistor arranged between the first fixed voltage terminal and the output terminal; and
a second variable resistor arranged between the second fixed voltage terminal and the output terminal.

7. A variable equalizer circuit configured to equalize a signal received via a transmission line from a device which is a communication partner device, the variable equalizer circuit comprising:
an input terminal connected to the transmission line;
an output terminal;
a first capacitor arranged between the output terminal and a fixed voltage terminal, and configured to have a variable capacitance;
a second resistor arranged between the input terminal and the output terminal;
a second capacitor arranged between the input terminal and the output terminal, and arranged in parallel with the second resistor;
a shunt resistor arranged on a path comprising the first capacitor and the second capacitor between the input terminal and the fixed voltage terminal; and
a level shifter configured to shift the voltage level of the output terminal, and to have a variable resistance between the output terminal and the fixed voltage terminal.

8. A variable equalizer circuit according to claim 7, wherein the shunt resistor comprises a fourth resistor between the output terminal and the fixed voltage terminal, and arranged in series with the first capacitor.

9. A variable equalizer circuit according to claim 7, wherein the shunt resistor comprises a third resistor arranged between the input terminal and a connection node that connects the second resistor and the second capacitor.

10. A variable equalizer circuit according to any one of claim 7, wherein the level shifter comprises:
a first fixed voltage terminal to which a first fixed voltage is to be applied;
a second fixed voltage terminal to which a second fixed voltage that differs from the first fixed voltage is to be applied;
a first variable resistor arranged between the first fixed voltage terminal and the output terminal; and
a second variable resistor arranged between the second fixed voltage terminal and the output terminal.

11. A test apparatus configured to receive a signal from a device under test via a transmission line, and to test the device under test, the test apparatus comprising:
a variable equalizer circuit configured to equalize a signal received from the device under test; and
a receiver circuit configured to receive an output signal from the variable equalizer circuit, wherein the variable equalizer circuit comprises:
an input terminal connected to the transmission line;
an output terminal;
a first resistor arranged between the output terminal and a fixed voltage terminal, and configured to have a variable resistance;
a first capacitor arranged between the output terminal and the fixed voltage terminal, arranged in parallel with the first resistor, and configured to have a variable capacitance;
a second resistor arranged between the input terminal and the output terminal;
a second capacitor arranged between the input terminal and the output terminal, and arranged in parallel with the second resistor; and
a shunt resistor arranged on a path including the first capacitor and the second capacitor between the input terminal and the fixed voltage terminal.

12. A test apparatus configured to receive a signal from a device under test via a transmission line, and to test the device under test, the test apparatus comprising:
a variable equalizer circuit configured to equalize a signal received from the device under test; and
a receiver circuit configured to receive an output signal from the variable equalizer circuit, wherein the variable equalizer circuit comprises:
an input terminal connected to the transmission line;
an output terminal;
a first capacitor arranged between the output terminal and a fixed voltage terminal, and configured to have a variable capacitance;
a second resistor arranged between the input terminal and the output terminal;
a second capacitor arranged between the input terminal and the output terminal, and arranged in parallel with the second resistor;
a shunt resistor arranged on a path comprising the first capacitor and the second capacitor between the input terminal and the fixed voltage terminal; and
a level shifter configured to shift the voltage level of the output terminal, and to have a variable resistance between the output terminal and the fixed voltage terminal.
